(19) United States
(12) Patent Application Publication
(10) Pub. No.: US 2025/0048886 A1
(43) Pub. Date: Feb. 6, 2025

(54) DISPLAY DEVICE

(71) Applicant: LG ELECTRONICS INC., Seoul (KR)

(72) Inventors: Jonggil Pyo, Seoul (KR); Myungho Lee, Seoul (KR); Jaehun Lee, Seoul (KR)

(73) Assignee: LG ELECTRONICS INC., Seoul (KR)

(21) Appl. No.: 18/663,278

(22) Filed: May 14, 2024

(30) Foreign Application Priority Data
Aug. 2, 2023 (KR) 10-2023-0100846

(51) Int. Cl. H10K 59/80

(52) U.S. Cl. CPC H10K 59/871; H10K 59/8792

(57) ABSTRACT

A display device is provided. The display device of the present disclosure includes: a display panel configured to display an image and having light transparency; a transparent panel facing the display panel; a side frame adjacent to a side edge of the display panel and elongated along the side edge of the display panel, and coupled to the transparent panel; a belt embedded in the side frame and moving in a longitudinal direction of the side frame; a bar elongated in a direction intersecting the side frame, the bar having one end fixed to the belt; a rotatable roller adjacent to a lower side connected to the side edge of the display panel, and elongated along the lower side of the display panel; and a light-shielding film having one end fixed to the bar and another end coupled to the roller, such that when the bar moves, the light-shielding film is wound around or unwound from the roller, wherein the bar includes: a plurality of pieces facing each other so that the light-shielding film is inserted between the facing pieces; and a belt fixer opposite to the plurality of pieces with respect to the belt, and coupled to the plurality of pieces.

### BACKGROUND OF THE INVENTION

### 1. Field of the Invention

The following description relates to a display device, and more particularly to a display device having a transparent display panel.

### 2. Description of the Related Art

With the development of the information society, there have been growing demands for various types of display devices, and in order to meet these demands, various display devices, such as a liquid crystal display (LCD) device, a plasma display panel (PDP), an electroluminescent display (ELD), a vacuum fluorescent display (VFD), an Organic Light Emitting Diode (OLED), etc., have been studied and used recently.

Among these devices, the LCD panel includes a TFT substrate and a color substrate which are positioned opposite each other with a liquid crystal layer interposed therebetween, and displays an image by using light provided by a backlight unit. Further, the OLED panel displays an image by using a self-emitting organic layer deposited on a substrate on which transparent electrodes are formed.

Recently, a transparent display panel, which not only displays an image for a user but also allows the user to see the back of the display, is being actively researched.

### SUMMARY OF THE INVENTION

It is an objective of the present disclosure to solve the above and other problems.

It is another objective of the present disclosure to provide a display device having a transparent display panel.

It is yet another objective of the present disclosure to provide a structure and drive mechanism for opening and closing the rear surface of a transparent display panel.

It is further another objective of the present disclosure to provide a frame structure in which a transparent display panel and a light-shielding film are coupled.

In accordance with an aspect of the present disclosure, the above and other objectives can be accomplished by providing a display device including: a display panel configured to display an image and having light transparency; a transparent panel facing the display panel; a side frame adjacent to a side edge of the display panel and elongated along the side edge of the display panel, and coupled to the transparent panel; a belt embedded in the side frame and moving in a longitudinal direction of the side frame; a bar elongated in a direction intersecting the side frame, the bar having one end fixed to the belt; a rotatable roller adjacent to a lower side connected to the side edge of the display panel, and elongated along the lower side of the display panel; and a light-shielding film having one end fixed to the bar and another end coupled to the roller, such that when the bar moves, the light-shielding film is wound around or unwound from the roller, wherein the bar includes: a plurality of pieces facing each other so that the light-shielding film is inserted between the facing pieces; and a belt fixer opposite to the plurality of pieces with respect to the belt, and coupled to the plurality of pieces.

### Effects of the Invention

The display device according to the present disclosure has the following effects.

According to at least one of the embodiments of the present disclosure, a display device having a transparent display panel may be provided.

According to at least one of the embodiments of the present disclosure, a structure and drive mechanism for opening and closing the rear surface of a transparent display panel may be provided.

According to at least one of the embodiments of the present disclosure, there may be provided a frame structure in which a transparent display panel and a light-shielding film are coupled.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF THE DRAWINGS

FIGS. 1 to 34 are diagrams illustrating examples of a display device according to embodiments of the present disclosure.

### DETAILED DESCRIPTION OF THE PREFERRED EMBODIMENTS

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms, “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended for limiting the scope of the present disclosure.

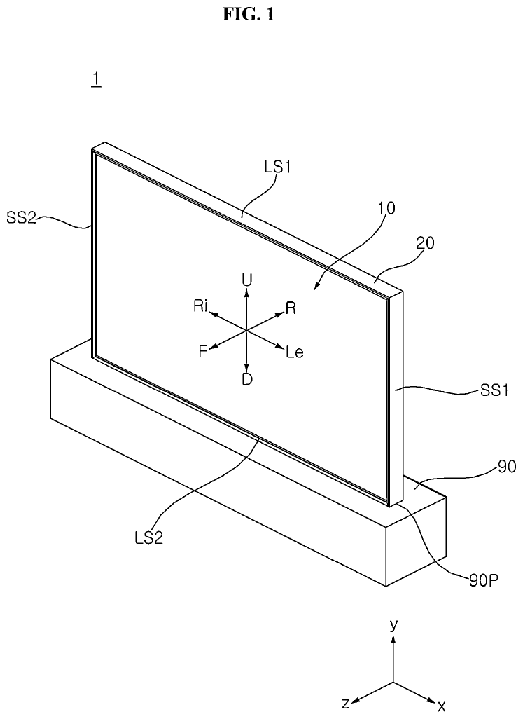

Referring to FIG. 1, a display device 1 may include a display 10, a side frame 20, and a housing 90. The display 10 may display an image. The side frame 20 may extend along a periphery of the display 10. The housing 90 may be disposed on a lower side of the display 10 and the side frame 20. Alternatively, the housing 90 may be disposed on an upper side, left side, or lower side of the display 10 and the side frame 20.

The display 10 may include a first long side LS1, a second long side LS2 opposite to the first long side LS1, a first short side SS1 adjacent to the first long side LS1 and the second long side LS2, and a second short side SS2 opposite to the first short side SS1. For convenience of explanation, it is illustrated and described that the first and second long sides LS1 and LS2 are longer than the first and second short sides SS1 and SS2, but it is also possible that lengths of the first and second long sides LS1 and LS2 may be approximately equal to or longer than lengths of the first and second short sides SS1 and SS2.

A direction parallel to the long sides LS1 and LS2 of the display 10 may be referred to as a left-right direction. A direction parallel to the short sides SS1 and SS2 of the display 10 may be referred to as an up-down direction. A direction perpendicular to the long sides LS1 and LS2 and the short sides SS1 and SS2 of the display 10 may be referred to as a front-rear direction.

A side on which the display 10 displays an image may be referred to as a front side F, z, and a side opposite thereto may be referred to as a rear side R. The first short side SS1 may be referred to as a left side Le, x, and the second short side SS2 may be referred to as a right side Ri, −x. The first long side LS1 may be referred to as an upper side U, y, and the second long side LS2 may be referred to as a lower side D.

Although an organic light emitting display (OLED) will be exemplified as a display panel hereinafter, a display panel applicable to the present disclosure is not limited thereto.

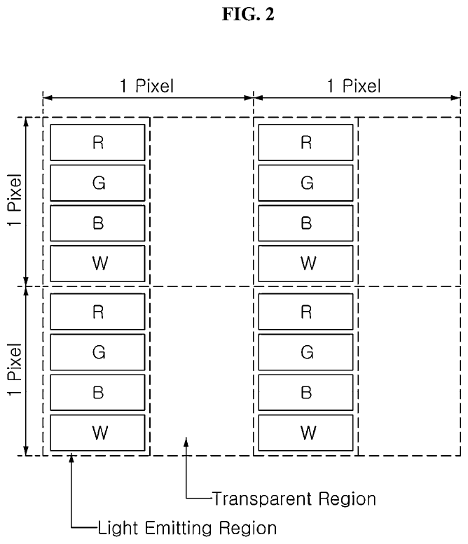

Referring to FIG. 2, each pixel includes a light emitting region and a transparent region. Red, Green, Blue, and White (RGBW) subpixels may be arranged vertically in the light emitting region, and the transparent region with no subpixels may be disposed next to the light emitting region.

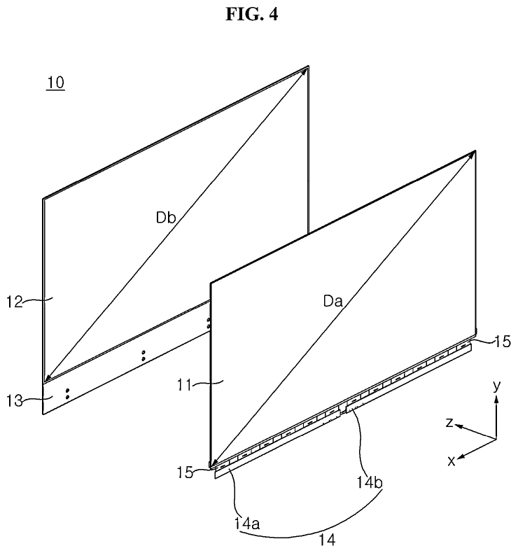

Accordingly, a display panel 11 (see FIG. 4) having a plurality of pixels may not only display an image, but also allow light to pass through. The display panel 11 (see FIG. 4) may be referred to as a transparent display panel or a transparent OLED panel.

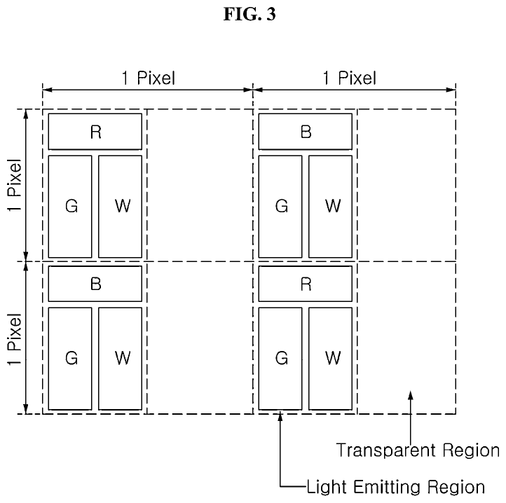

Referring to FIG. 3, each pixel includes a light emitting region and a transparent region. Red, Green, and White (RGW) subpixels or Blue, Green, and White (BGW) subpixels may be arranged next to each other in the light emitting region, and the transparent region with no subpixels may be disposed next to the light emitting region.

Accordingly, the display panel 11 (see FIG. 4) having a plurality of pixels may not only display an image, but also allow light to pass through. The display panel 11 (see FIG. 4) may be referred to as a transparent display panel or a transparent OLED panel.

Referring to FIG. 4, the display panel 11 may divide an image into a plurality of pixels and may output the image while controlling color, brightness, and chroma of the respective pixels. The display panel 11 may be divided into an active area AA, in which an image is displayed, and a de-active area DA in which no image is displayed. The display panel 11 may generate light corresponding to red (R), green (G), or blue (B) color in response to a control signal.

A source PCB 14 may be adjacent to a lower side of the display panel 11. The source PCB 14 may extend along the lower side of the display panel 11. The source PCB 14 may be electrically connected to the display panel 11 through a Chip On Film (COF). The source PCB 14 may be electrically connected to a timing controller board (T-CON board) through a cable (not shown) such as a Flexible Flat Cable (FFC).

A transparent panel 13 may be disposed at the front of the display panel 11. The transparent panel 13 may be glass having a transparent material. An adhesive film 12 may be disposed between the display panel 11 and the transparent panel 13 and may be bonded to the display panel 11 and the transparent panel 13. The adhesive film 12 may be an Optically Clear Adhesive (OCA) Film. The transparent panel 13 may be referred to as a front panel 13.

The adhesive film 12 may cover at least partially a rear surface of the transparent panel 13. For example, one side of the adhesive film 12 may be disposed closer to the center of the display panel 11 than one side of the transparent panel 13. A size or area of the adhesive film 12 may be smaller than a size or area of the transparent panel 13. For example, each of the upper side, left side, and right side of the adhesive film 12 may be next to the upper side, left side, and right side, respectively, of the transparent panel 13, and the lower side of the adhesive film 12 may be spaced upward from the lower side of the transparent panel 13.

The size of the adhesive film 12 may correspond to the size of the display panel 11. For example, a diagonal length Db of the adhesive film 12 may be substantially equal to a diagonal length Da of the display panel 11. In another example, the diagonal length Db of the adhesive film 12 may be greater than the diagonal length Da of the display panel 11. A portion of the adhesive film 12 may be disposed along a periphery of the display panel 11 on the outside of the display panel 11. For example, the adhesive film 12 may form a rectangular line along the edges of the display panel 11.

The display panel 11, the adhesive film 12, and the transparent panel 13 may be referred to as the display 10.

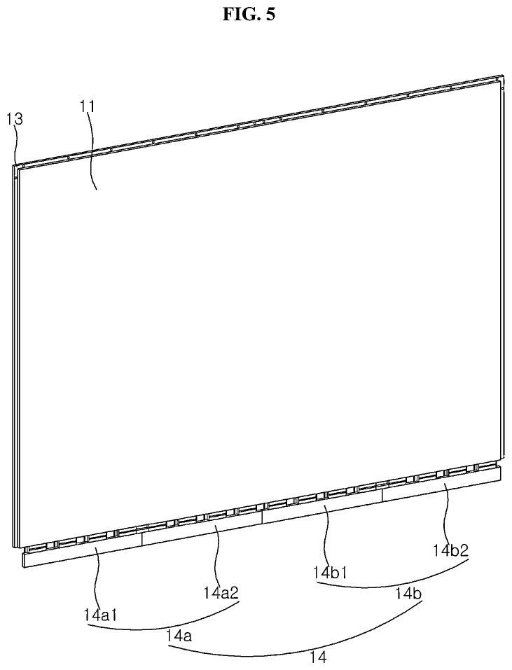

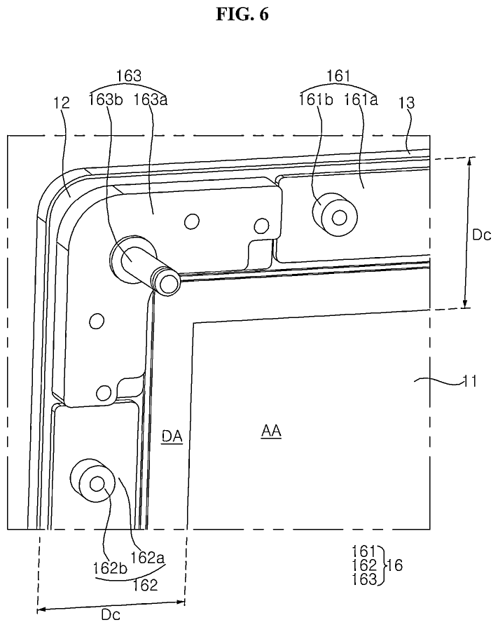

Referring to FIGS. 5 and 6, the adhesive film 12 may be disposed along the periphery of a rear surface that is adjacent to edges of the transparent panel 13. The adhesive film 12 may be elongated and attached to the rear surface of the transparent panel 13. The adhesive film 12 may have a predetermined width Dc.

The display panel 11 may be disposed on the rear surface of the transparent panel 13. A front surface adjacent to the edges of the display panel 11 may overlap the adhesive film 12. An area where the display panel 11 and the adhesive film 12 overlap each other may be the de-active area DA of the display panel 11. The display panel 11 may be adhered or fixed to the adhesive film 12. For example, the adhesive film 12 may have a black color, and the de-active area DA of the display panel 11 may be covered by the adhesive film 12.

A frame fixer 16 may include a horizontal fixer 161, a vertical fixer 162, and a corner fixer 163. The horizontal fixer 161 may include a plate 161a and a PEM nut 161b. The plate 161a may be elongated in the left-right direction and fixed to the adhesive film 12. The PEM nut 161b may be formed on the plate 161a. The PEM nut 161b may protrude rearward from an outer surface of the plate 161a.

The vertical fixer 162 may include a plate 162a and a PEM nut 162b. The plate 162a may be elongated in the up-down direction and fixed to the adhesive film 12. The PEM nut 162b may be formed on the plate 162a. The PEM nut 162b may protrude rearward from an outer surface of the plate 162a.

The corner fixer 163 may be a bent plate segment. The corner fixer 163 may be a plate 163a which is bent along the corner of the transparent panel 13. A pulley shaft 163b may extend by protruding from an outer surface of the plate 163a of the corner fixer 163 toward the rear of the transparent panel 13. The corner fixer 163 may be adhered or fixed to the adhesive film 12. The corner fixer 163 may be referred to as a right corner fixer 163 or a first corner fixer 163.

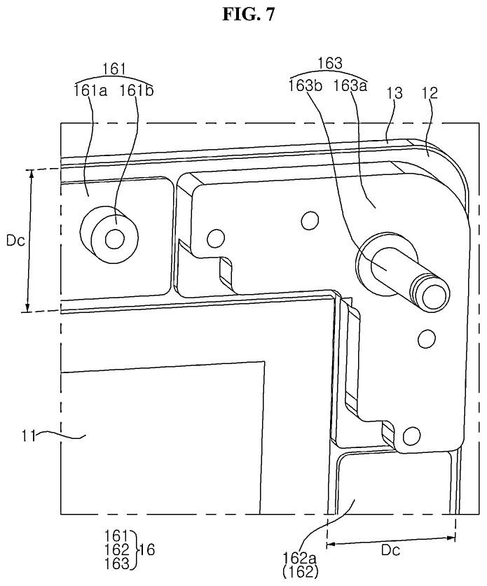

Referring to FIG. 7, a frame fixer 16 may include a horizontal fixer 161, a vertical fixer 162, and a corner fixer 163. The horizontal fixer 161 may include a plate 161a and a PEM nut 161b. The plate 161a may be elongated in the left-right direction and may be fixed to the adhesive film 12. The PEM nut 161b may be formed on the plate 161a. The PEM nut 161b may protrude rearward from an outer surface of the plate 161a.

The vertical fixer 162 may be elongated in the up-down direction and may be fixed to the adhesive film 12.

The corner fixer 163 may be a bent plate segment. The corner fixer 163 may be a plate 163a which is bent along the corner of the transparent panel 13. A pulley shaft 163b may extend by protruding from an outer surface of the plate 163a of the corner fixer 163 toward the rear of the transparent panel 13. The corner fixer 163 may be adhered or fixed to the adhesive film 12. The corner fixer 163 may be referred to as a left corner fixer 163 or a second corner fixer 163.

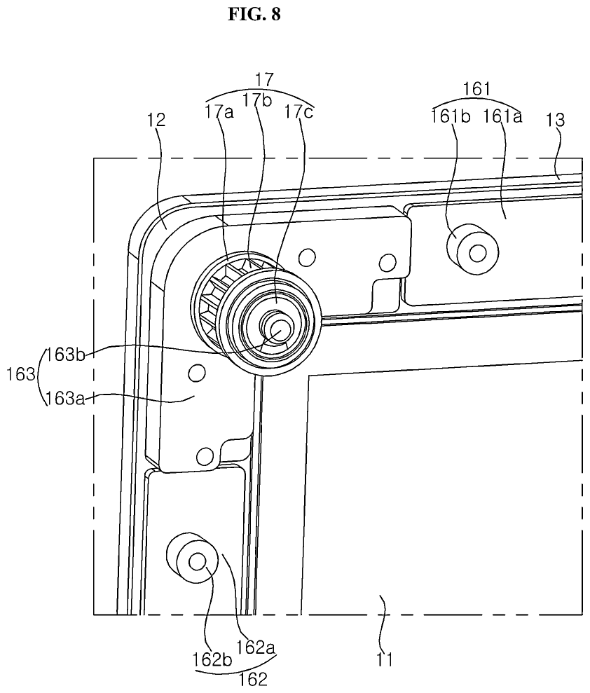

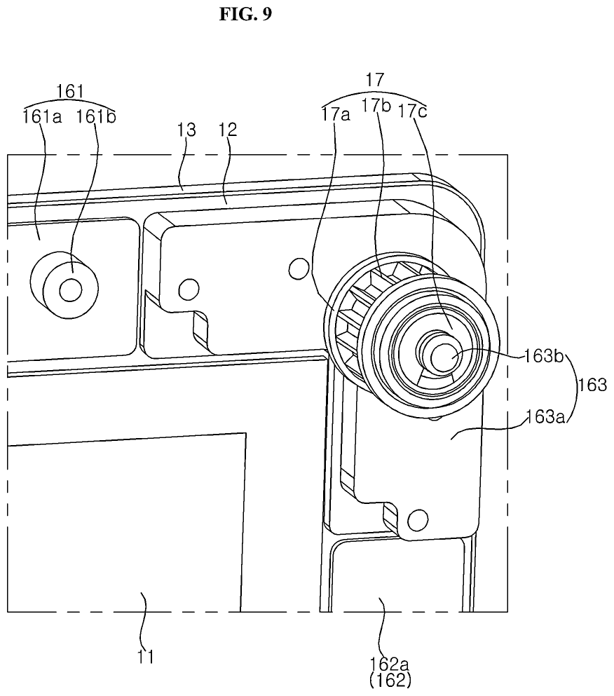

Referring to FIGS. 8 and 9, a pulley 17 may be inserted into the pulley shaft 163b. The pulley 17 may rotate on the pulley shaft 163b. The pulley 17 may be referred to as an upper pulley 17. For example, a lubricant may be applied between the pulley shaft 163b and the pulley 17 to prevent noise. In another example, the pulley 17 may be made of a synthetic resin with low frictional resistance, and the pulley shaft 163b may include metal to prevent noise and facilitate smooth rotation of the pulley 17.

The pulley 17 may include a wheel 17a and a belt gear 17b. The wheel 17a may be formed in a ring or rim shape. The pulley shaft 163b may be inserted into the wheel 17a, and the wheel 17a may rotate on the pulley shaft 163b. The belt gear 17b may form an outer circumferential surface of the wheel 17a. A lock washer 17c may be adjacent to a distal end of the pulley shaft 163b and may be coupled to the pulley shaft 163b. For example, the lock washer 17c may be an E-ring. The lock washer 17c may prevent the pulley 17 from being separated from the pulley shaft 163b. A first pulley 17 (see FIG. 8) or a right pulley 17 (see FIG. 8) may be disposed on the first corner fixer 163 or the right corner fixer 163, and a second pulley 17 (see FIG. 9) or a left pulley 17 (see FIG. 9) may be disposed on the second corner fixer 163 or the left corner fixer 163.

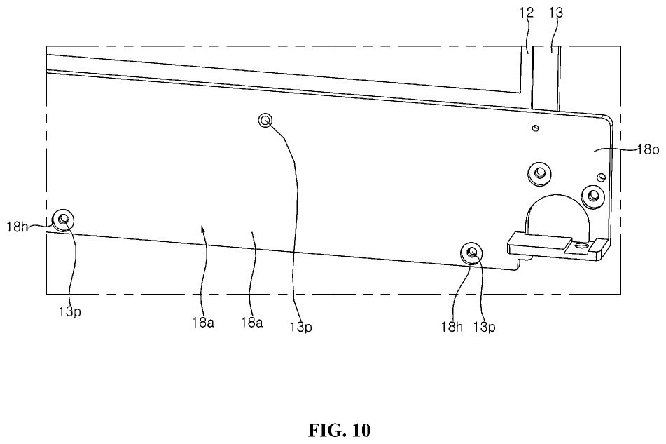

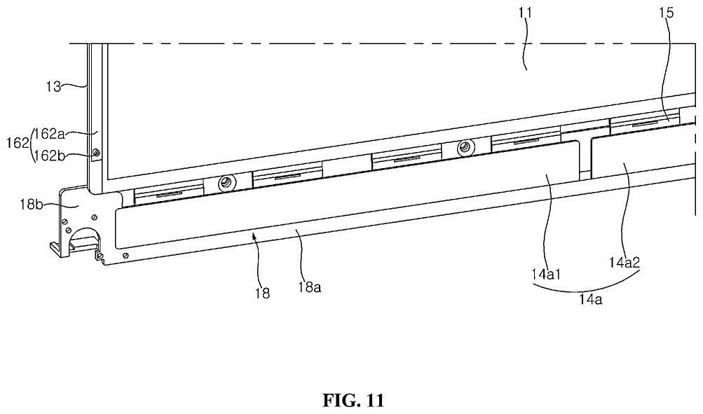

Referring to FIGS. 10 and 11, a lower frame 18 may be coupled to a lower side of the transparent panel 13. The lower frame 18 may be an elongated plate. Referring also to FIG. 4, an area or size of the transparent panel 13 may be greater than an area or size of the display panel 11. For example, the transparent panel 13, except the lower side thereof, may be covered by the display panel 11. The lower frame 18 may be coupled via a PEM nut 13P to the lower side of the transparent panel 13 which is adjacent to a lower edge of the transparent panel 13.

The lower frame 18 may include a plurality of fastening holes 18h, and the PEM nuts 13P of the transparent panel 13 may be inserted into the fastening holes 18h of the lower frame 18. A length of the lower frame 18 may be greater than a length of the lower side of the transparent panel 13. The lower frame 18 may include a center plate 18a and a side mount 18b. The side mount 18b may extend from the center plate 18a to form the left and right sides of the lower frame 18 and may extend further from the left and right edges of the transparent panel 13.

The display panel 11 may be fixed to the transparent panel 13 by the adhesive film 12, and an S-PCB 14 may be disposed on a rear surface of the center plate 18a of the lower plate 18. There may be a plurality of S-PCBs 14. A first S-PCB 14al may be next to a second S-PCB 14a2. The second S-PCB 14a2 may be sequentially disposed in a longitudinal direction of the first S-PCB 14al. A COF 15 may connect the S-PCB 14 to the lower side of the display panel 11.

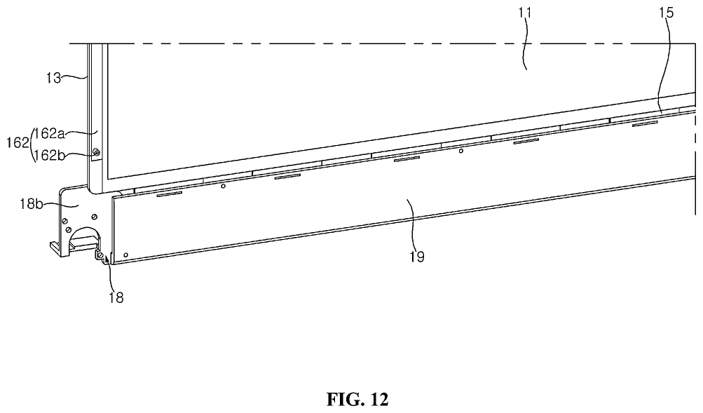

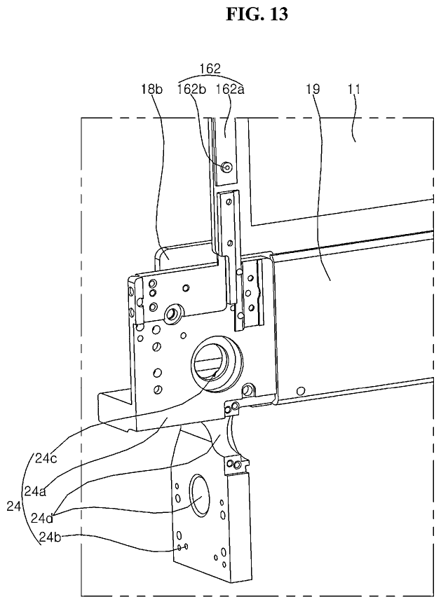

Referring to FIGS. 12 and 13, a PCB cover 19 may cover an S-PCB 14a (see FIG. 11). The PCB cover 19 may be elongated, may cover the S-PCBs 14 and 14a (see FIGS. 4 and 11), and may be coupled or fixed to the lower plate 18. The PCB cover 19 may be formed as an electromagnetic shielding member.

A mount bracket 24 may be coupled to the side mount 18b of the lower plate 18. There may be a plurality of mount brackets 24, each of which may be coupled to the side mount 18b on the left and right sides. The mount bracket 24 may include a gear mount 24a and a motor mount 24b. The gear mount 24a may face the side mount 18b and may be fixed to the side mount 18b. The motor mount 24b may extend from the gear mount 24a or may be connected to the gear mount 24a. The motor mount 24a may be referred to as a roller mount 24a.

The gear mount 24a may have a gear hole 24c. The gear hole 24c may be a hole formed through the gear mount 24a. The motor mount 24b or the roller mount 24b may have a roller hole 24d. There may be a plurality of roller holes 24d. For example, one roller hole 24d may be a circle, and another roller 24d may be a half-circle. A roller 72 which will be described later may be rotatably coupled to the roller hole 24d having a circular shape, and a guide roller 73 may be rotatably coupled to the roller hole 24d having a half-circular shape.

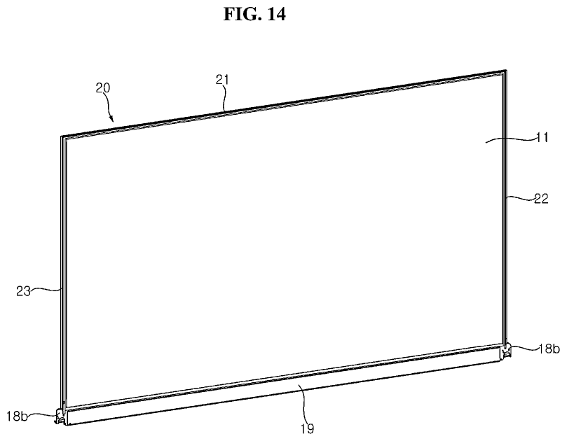

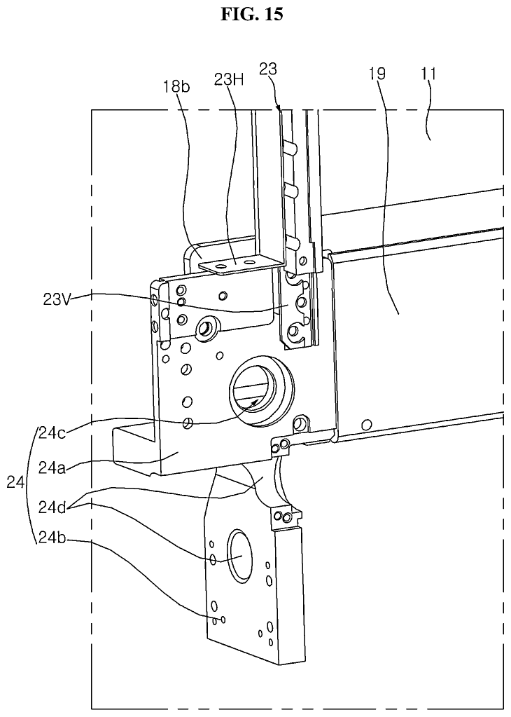

Referring to FIGS. 14 and 15, the side frame 20 may include a first part 21, a second part 22, and a third part 23. The first part 21 may be referred to as a horizontal side frame 21, the second part 22 may be referred to as a first vertical side frame 22, and the third part 23 may be referred to as a second vertical side frame 23.

The side frame 20 may be coupled or fixed to the frame fixer 16 (see FIGS. 6 and 7). The first part 21 may be coupled or fixed to the horizontal fixer 161, the second part 22 may be coupled or fixed to the vertical fixer 162, and the third part 23 may be coupled or fixed to the vertical fixer 162.

A distal end of the third part 23 may include a vertical fixing part 23V and a horizontal fixing part 23H. The horizontal fixing part 23H may be fastened or fixed to a lateral side of the gear mount 24a, and the vertical fixing part 23V may be fastened or fixed to a plane of the gear mount 24A. The description of the third part 23 may also apply to the second part 22.

Accordingly, it is possible to prevent twisting of the side frame 20.

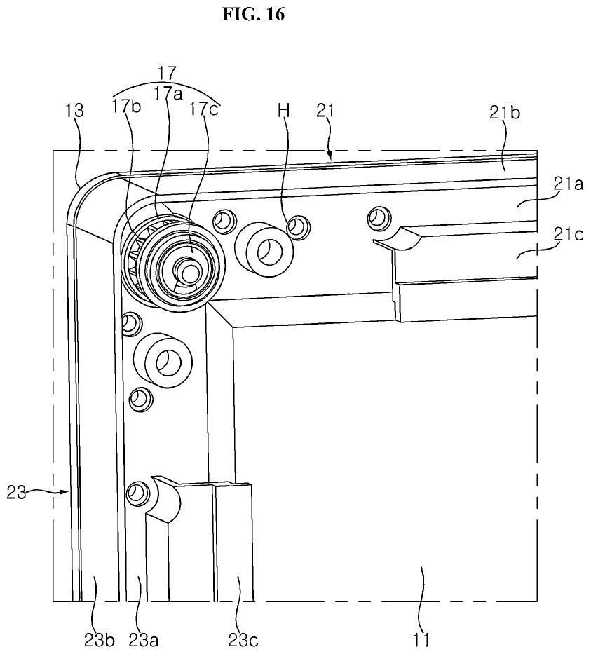

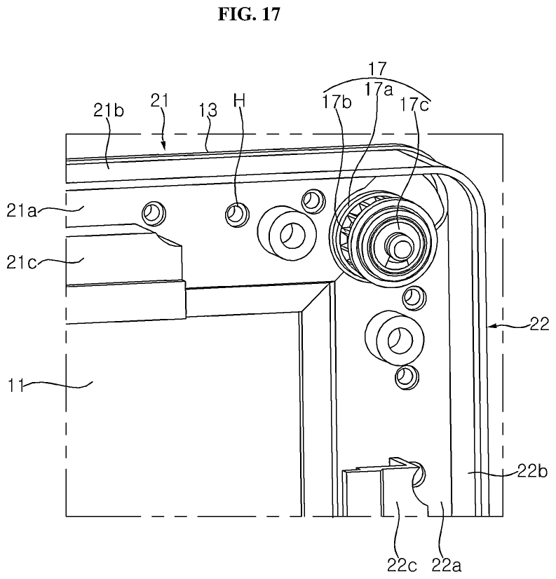

Referring to FIGS. 16 and 17, the first part 21 may include a base plate 21a, a cover plate 21b, and a rail 21c. The base plate 21a may be a plate fixed to the horizontal fixer 161. The cover plate 21b may be a plate adjacent to an edge of the transparent panel 13 and bent from an edge of the base plate 21a to extend in a thickness direction of the transparent panel 13. The rail 21c may be formed on the base plate 21a. The rail 21c may extend in a longitudinal direction of the base plate 21a. The rail 21c may be referred to as a horizontal rail 21c.

The second part 22 may include a base plate 22a, a cover plate 22b, and a rail 22c. The base plate 22a may be a plate fixed to the vertical fixer 163. The cover plate 22b may be a plate adjacent to an edge of the transparent panel 13 and bent from an edge of the base plate 22a to extend in a thickness direction of the transparent panel 13. The rail 22c may be formed on the base plate 22a. The rail 22c may extend in a longitudinal direction of the base plate 22a. The rail 22c may be referred to as a vertical rail 22c.

The third part 23 may include a base plate 23a, a cover plate 23b, and a rail 23c. The base plate 23a may be a plate fixed to the vertical fixer 163. The cover plate 23b may be a plate adjacent to an edge of the transparent panel 13 and bent from an edge of the base plate 23a to extend in a thickness direction of the transparent panel 13. The rail 23c may be formed on the base plate 23a. The rail 23c may extend in a longitudinal direction of the base plate 23a. The rail 23c may be referred to as a vertical rail 23c.

The cover plate 21b of the first part 21 may be integrally connected with the cover plate 22b of the second part 22. The cover plate 21b of the first part 21 may be integrally connected with the cover plate 23b of the third part 23. The cover plates 21b, 22b, and 23b may have rounded corners. The pulleys 17 may be adjacent to the corners of the cover plates 21b, 22b, and 23b and may be disposed inside the side frames 21, 22, and 23. The side frames 21, 22, and 23 have fastening holes H to be fixed by screws to the horizontal fixer 161 (see FIGS. 8 and 9) and/or the vertical fixer 163 (see FIGS. 8 and 9).

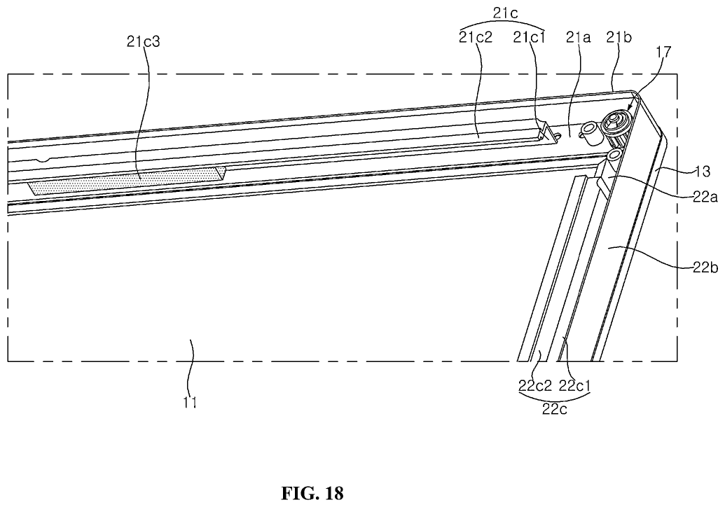

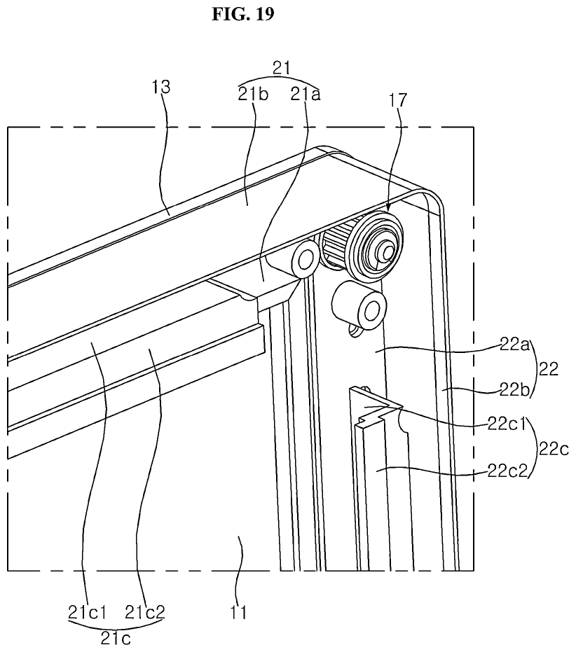

Referring to FIGS. 18 and 19, the horizontal rail 21c may include a rail wall 21cl and a rail cover 21c2. The rail wall 21cl may form a wall from the base plate 21a and may extend in a longitudinal direction of the base plate 21a. The rail cover 21c2 may be bent vertically downwardly from the rail wall 21cl. A length of the rail cover 21c2 may correspond to a length of the rail wall 21c1.

A lever stopper 21c3 may be fixed to the horizontal rail 21c. The lever stopper 21c3 may be fixed to the rail wall 21cl and/or the rail cover 21c2 of the horizontal rail 21c. For example, the lever stopper 21c3 may be an elastic body.

The vertical rail 22c may include a rail wall 22cl and a rail cover 22c2. The rail wall 22cl may form a wall from the base plate 22a and may extend in a longitudinal direction of the base plate 22a. The rail cover 22c2 may be bent vertically from the rail wall 22cl toward the display panel 11. A length of the rail cover 22c2 may correspond to a length of the rail wall 22c1.

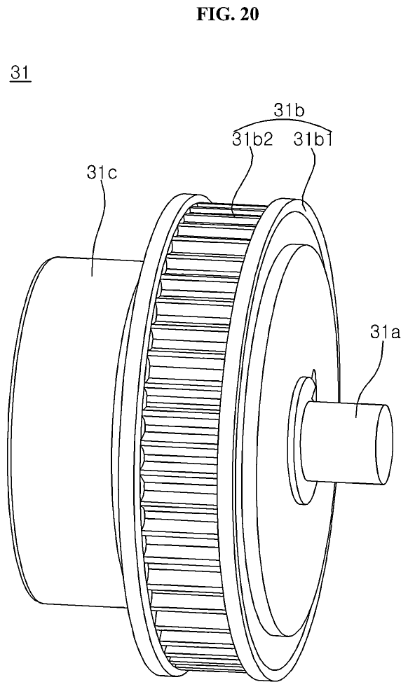

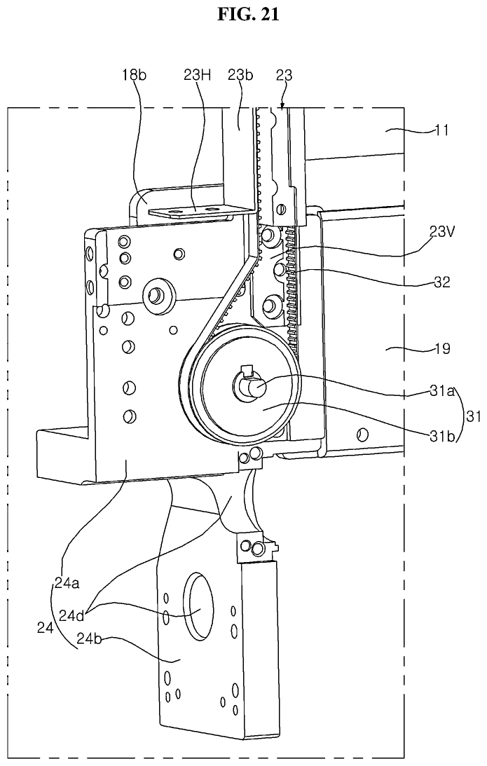

Referring to FIGS. 20 and 21, a pulley assembly 31 may include a driving pulley 31b, a pulley shaft 31a, and a bearing 31c. The pulley assembly 31 may be referred to as a lower pulley assembly 31, and the driving pulley 31b may be referred to as a lower pulley 31b. A rim 31b1 may be fixed to the pulley shaft 31a. When the pulley shaft 31a rotates, the rim 31b1 may also rotate. The rim 31b1 may have a cylindrical shape. A belt gear 31b2 may be formed on an outer circumferential surface of the rim 31b1. The bearing 31c may be inserted and fixed into the gear hole 24c (see FIG. 15). The pulley shaft 31a may be coupled to the bearing 31c.

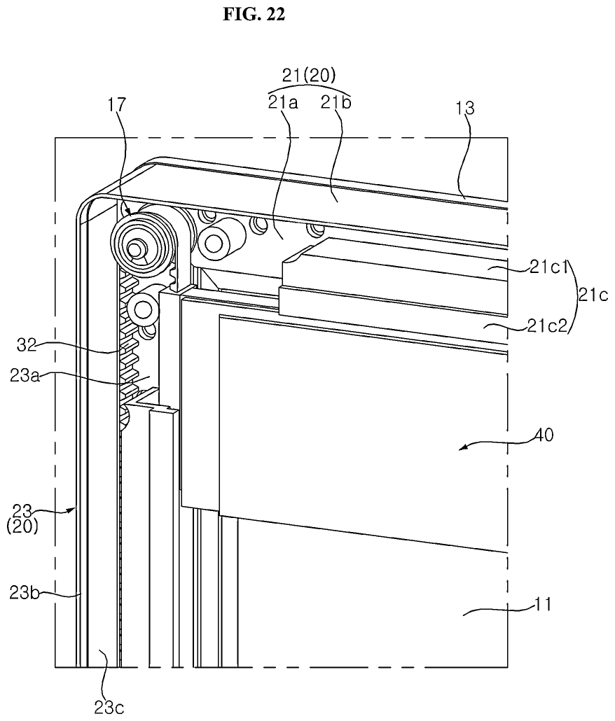

Referring to FIG. 22 along with FIG. 21, the driving belt 32 may be wound around the driving pulley 31b. The driving belt 32 may be embedded in the third part 23 of the side frame 20. For example, the belt 32 may be a timing belt. The belt 32 may be wound around the driving pulley 31b and the pulley 17. The belt 32 may be arranged so that opposing sides thereof may face each other with respect to the third part 23 of the side frame 20.

A bar 40 may be disposed parallel to the first part 21 of the side frame 20. The bar 40 may be fixed to the belt 32 to move up and down by the belt 32. The bar 40 may be inserted into the rail 23c of the third part 23 and may move up and down on the rail 23c.

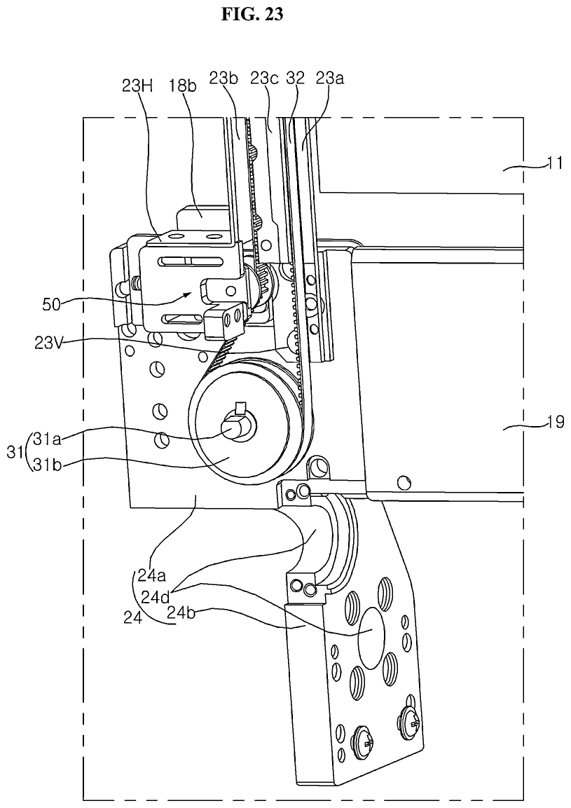

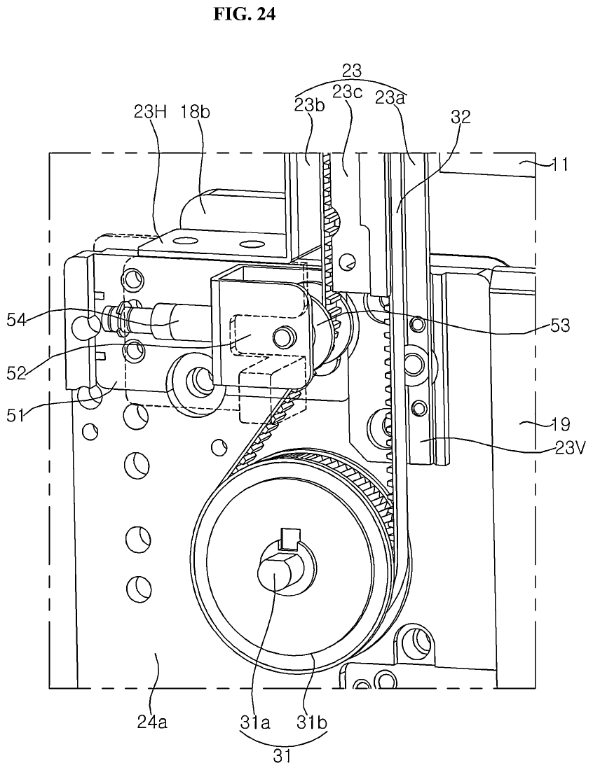

Referring to FIGS. 23 and 24, a tensioner 50 may include a housing 51, a piston 54, a wheel housing 52, and a wheel 53. The housing 51 defines an internal accommodation space and may be coupled to the gear mount 24a. The wheel housing 52 may be disposed inside the housing 51 and may move within the housing 51. The wheel 53 may be rotatably coupled to the wheel housing 52. A first end of the piston 54 may be supported by the housing 51 or fixed thereto, and a second end of the piston 54 may be fixed to the wheel housing 52. For example, the piston 54 may be a shock absorber.

The tensioner 50 may push an outer surface of the belt 32. By the tensioner 50, the spacing of the belt 32 may be maintained smaller than a diameter of the pulley 31b. The spacing of the belt 32, which is maintained by the tensioner 50, may correspond to the diameter of the pulley 17 (see FIG. 22).

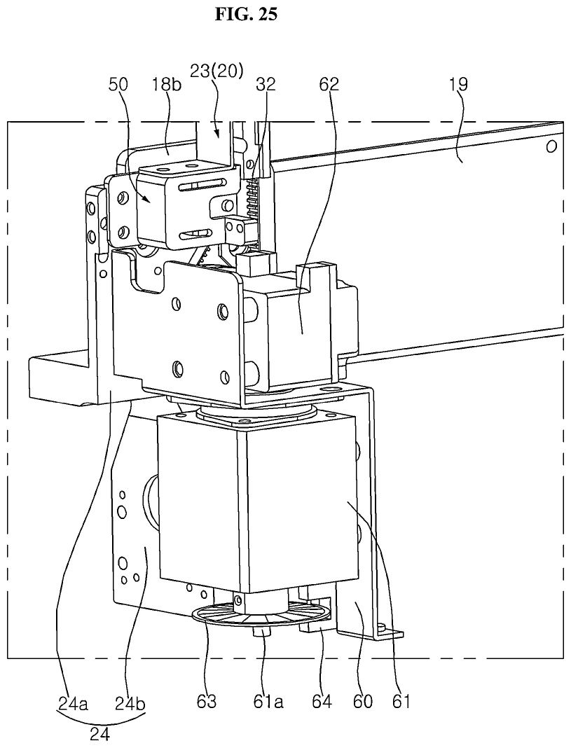

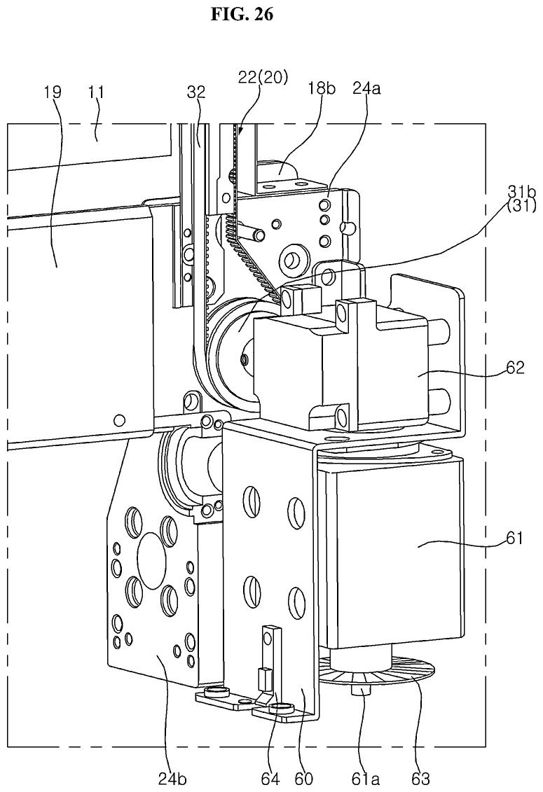

Referring to FIGS. 25 and 26, a fixing bracket 60 may be coupled or fixed to the gear mount 24a and/or the motor mount 24b. A motor 61 and a gear box 62 may be coupled or fixed to the fixing bracket 60.

The fixing bracket 60 may be a plate bent a plurality of times. The motor 61 may be disposed on one side of the fixing bracket 60, and the gear box 62 may be disposed on another side of the fixing bracket 60. The gear box 62 may be opposite to the motor 61 with respect to the fixing bracket 60. The motor 61 may provide torque to the gear box 62. The gear box 62 may be connected to the pulley assembly 31. The gear box 62 may rotate the driving pulley 31b.

A rotation counter 63 may be fixed to a rotating shaft 61a of the motor 61. A sensor 64 may be fixed to the fixing bracket 60 to detect rotation of the rotation counter 63. For example, the sensor 64 may be a photosensor.

The torque provided by the motor 61 may be transferred to the driving pulley 31b through the gear box 62, and when the driving pulley 31b rotates, the belt 32 may move up and down.

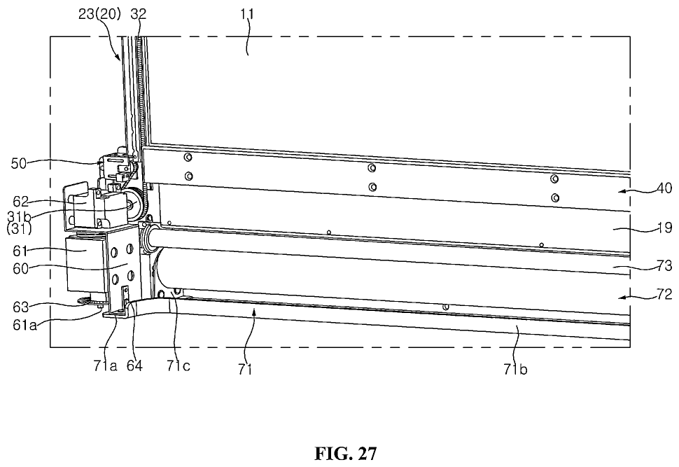

Referring to FIG. 27, a bottom frame 71 may be coupled to the fixing bracket 60. The bottom frame 71 may be formed by pressing a horizontally elongated plate. The bottom frame 71 may include under covers 71a and 71b forming a bottom and coupled to the fixing bracket 60. The under covers 71a and 71b may include a horizontal base 71a forming a bottom surface, and a vertical base 71b bent from the horizontal base 71a and forming a wall.

The bottom frame 71 may further include a roller bracket 71c. The roller bracket 71c may be coupled or fixed to the horizontal base 71a of the bottom frame 71. The roller bracket 71c may be located adjacent or next to the fixing bracket 60. A plurality of rollers may be coupled to the roller bracket 71c.

The roller 72 may be elongated on the bottom frame 71, and may be rotatably coupled to the roller bracket 71c and/or the roller hole 24d (see FIG. 23) having a circular shape. The guide roller 73 may be disposed next to the roller 72 and may be rotatably coupled to the roller hole 24d (see FIG. 23) having a half-circular shape. The guide roller 73 may be elongated and parallel to the roller 72. For example, a diameter of the guide roller 73 may be smaller than a diameter of the roller 72.

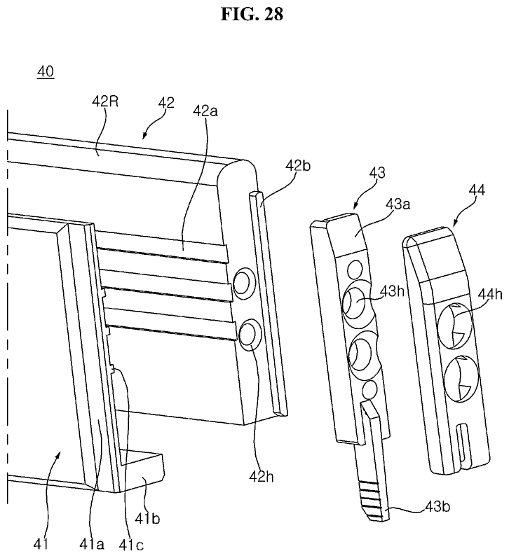

Referring to FIG. 28, the bar 40 may include a first piece 41, a second piece 42, a belt fixer 43, and a fixer cover 44. The first piece 41 may be coupled to the second piece 42. The first piece 41 may include a first part 41a and a second part 41b. The first part 41a may be in the shape of an elongated plate bar. The second part 41b may extend in a thickness direction of the first part 41a and may form a wall at an edge of the first part 41a. A fixing rib 41c may be formed on one surface of the first part 41a. The fixing rib 41c may be elongated in a longitudinal direction of the first part 41a. There may be a plurality of fixing ribs 41c. The plurality of fixing ribs 41c may be spaced apart from each other by a predetermined distance.

The second piece 42 may be in the shape of a plate bar extending to a length corresponding to the first part 41a of the first piece 41. A rib groove 42a may be elongated from one surface of the second piece 42 in a longitudinal direction of the second piece 42. There may be a plurality of rib grooves 42a, and the plurality of rib grooves 42a may be formed in one surface of the second piece 42a to correspond to the plurality of fixing ribs 41c. A side rib 42b may be formed on an end surface of the second piece 42 in a width direction of the second piece 42. A fastening hole 42h may be formed in the end surface of the second piece 42 at a position next to the side rib 42b. There may be a plurality of fastening holes 42h. An edge 42R of the second piece 42 may be rounded in a longitudinal direction of the second piece 42.

The belt fixer 43 may be coupled to end surfaces of the first piece 41 and the second piece 42. The belt fixer 43 may have a fastening hole 43h. The fastening hole 43h of the belt fixer 43 may correspond to the fastening hole 42h of the second piece 42. There may be a plurality of fastening holes 43h.

The fixer cover 44 may be coupled to the belt fixer 43. The fixer cover 44 may have an insertion hole 44h. The insertion hole 44h may correspond to the fastening hole 43h of the belt fixer 43. There may be a plurality of insertion holes 44h.

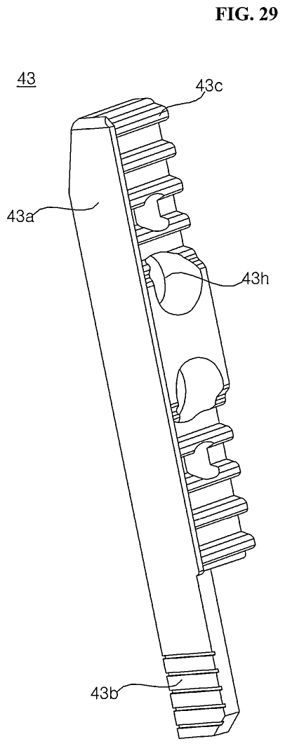

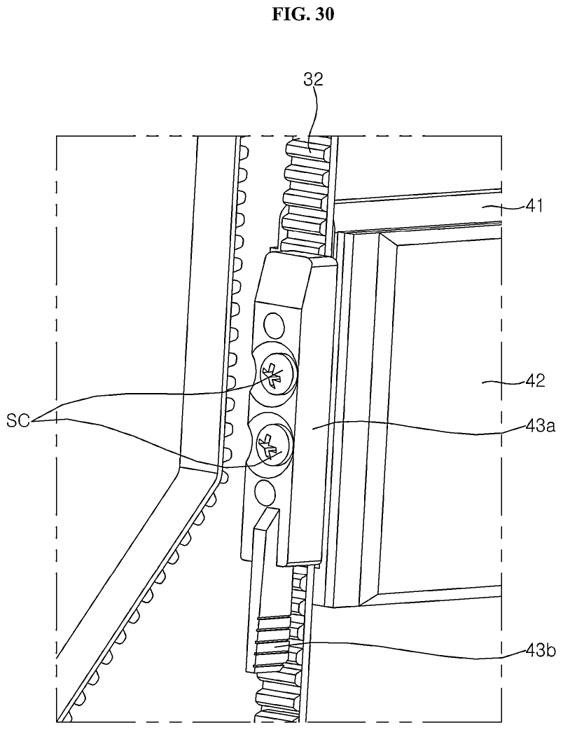

Referring to FIGS. 29 and 30, the belt fixer 43 may include a fixer body 43a and a fixer tail 43b. The fixer body 43a may be elongated and may have fastening holes 43h. A gear surface 43c may be formed on one surface of the fixer body 43a. The fixer tail 43b may be elongated from one end of the fixer body 43a in a longitudinal direction of the fixer body 43a. The fixer tail 43b may be an indicator of a position of the bar 40 (see FIG. 28).

The belt fixer 43 may be coupled to one end surface of the bar 40 while pressing the belt 32. A gear of the belt 32 and the gear surface 43c of the belt fixer 43 may be engaged with each other. A screw SC may be inserted into the fastening hole 43h to fix the belt fixer 43 to one end surface of the bar 40 (see FIG. 28), thereby preventing the belt 32 from slipping, and allowing precise up and down movement of the bar 40 (see FIG. 28).

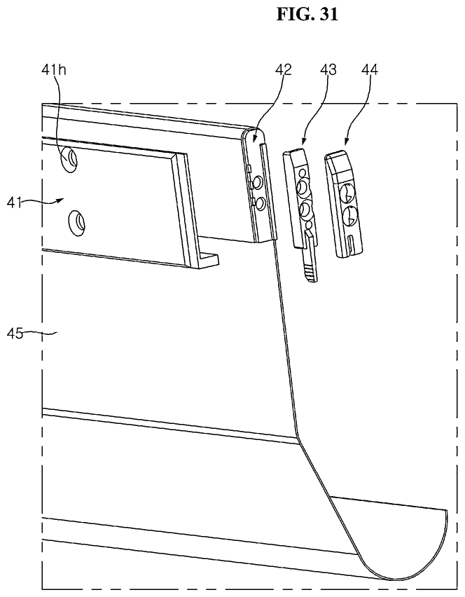

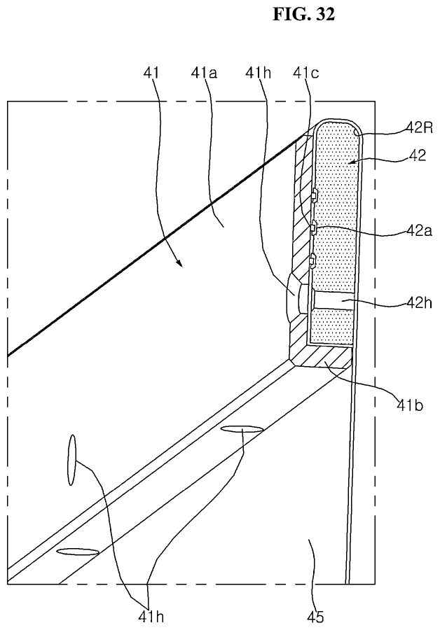

Referring to FIGS. 31 and 32, a light-shielding film 45 may be wound around the bar 40. The light-shielding film 45 is referred to as a cover layer 45 or a light-shielding layer 45. The light-shielding film 45 may cover an outer surface of the second piece 42, may be wound around the rounded edge 42R, and may be inserted between the first piece 41 and the second piece 42. The light-shielding film 45 may contact the first piece 41 and the second piece 42. The light-shielding film 45 may be disposed between the fixing rib 41c and the rib groove 42a. The fixing rib 41c may be inserted into the rib groove 42a to grip the light-shielding film 45. As the light-shielding film 45 is wound around the edge 42R of the rounded second piece 42, tight tension may be given to the light-shielding film 45.

A distal end of the light-shielding film 45 may be disposed between the first part 41a of the first piece 41 and the second piece 42. The distal end of the light-shielding film 45 may also be disposed between the second part 41b of the first piece 41 and the second piece 42. If the distal end of the light-shielding film 45 is disposed between the second part 41b of the first piece 41 and the second piece 42, the light-shielding film 45 may be more firmly fixed to the bar 40.

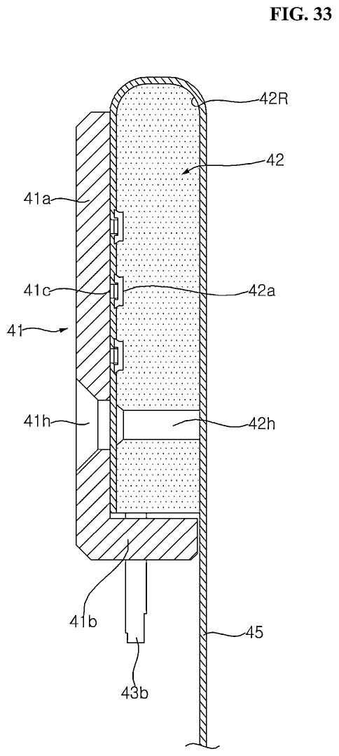

Referring to FIG. 33 along with FIG. 32, the second piece 42 may have a horizontal fastening hole 42h. The horizontal fastening hole 42h may be formed through the second piece 42 in a thickness direction of the second piece 42. The first part 41a of the first piece 41 may have a horizontal fastening hole 41h. The horizontal fastening hole 41h of the first piece 41 may correspond to the horizontal fastening hole 42h of the second piece 42. A fastening member may pass through the horizontal fastening hole 41h of the first piece 41 to be inserted and fixed into the horizontal fastening hole 42h of the second piece 42. In this case, a screw may pass through the light-shielding film 45. When the screw passes through the light-shielding film 45, wrinkles may be formed on the light-shielding film 45. As the fixing rib 41c is inserted into the rib groove 42a, the formation of wrinkles may be prevented.

Accordingly, as the light-shielding film 45 is firmly fixed to the bar 40, sufficient tension may be given to the light-shielding film 45, and the formation of wrinkles may be prevented.

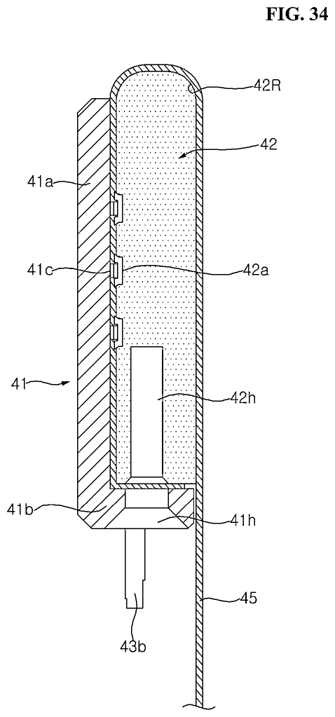

Referring to FIG. 34 along with FIG. 32, the second piece 42 may have a vertical fastening hole 42h. The vertical fastening hole 42h may be formed inside the second piece 42 in a width direction of the second piece 42. The second part 41b of the first piece 41 may have a vertical fastening hole 41h. The vertical fastening hole 41h of the first piece 41 may correspond to the vertical fastening hole 42h of the second piece 42. A fastening member may pass through the vertical fastening hole 41h of the first piece 41h to be inserted and fixed into the vertical fastening hole 42h of the second piece 42. In this case, a screw may pass through the light-shielding film 45. When the screw passes through the light-shielding film 45, wrinkles may be formed on the light-shielding film 45. As the fixing rib 41c is inserted into the rib groove 42a, the formation of wrinkles may be prevented.

Accordingly, as the light-shielding film 45 is firmly fixed to the bar 40, sufficient tension may be given to the light-shielding film 45, and the formation of wrinkles may be prevented.

Referring to FIGS. 1 to 34, a display device includes: a display panel 11 configured to display an image and having light transparency; a transparent panel 13 facing the display panel 13; a side frame 22 and 23 adjacent to a side edge of the display panel 11 and elongated along the side edge of the display panel 11, and coupled to the transparent panel 13; a belt 32 embedded in the side frame 22 and 23 and moving in a longitudinal direction of the side frame 22 and 23; a bar 40 elongated in a direction intersecting the side frame 22 and 23, the bar 40 having one end fixed to the belt 32; a rotatable roller 72 adjacent to a lower side connected to the side edge of the display panel 11, and elongated along the lower side of the display panel 11; and a light-shielding film 45 having one end fixed to the bar 40 and another end coupled to the roller 72, such that when the bar 40 moves, the light-shielding film 45 is wound around or unwound from the roller 72.

The display device may further include: a lower frame 18 elongated along the lower side of the display panel 11 and coupled to the transparent panel 13; a driving pulley assembly 31 which is rotatably coupled to the lower frame 18, and around which the belt 32 is wound; and an upper pulley 17 which is rotatably disposed on the side frame 22 and 23, and around which the belt 32 is wound.

The display device may further include a frame fixer 16 disposed between the side frame 22 and 23 and the transparent panel 13 and fixed to the transparent panel 13, wherein the upper pulley 17 may rotate on a pulley shaft 163b protruding from the frame fixer 16 and extending inside the side frame 22 and 23.

The display device may further include a mount bracket 24 adjacent to a distal end of the side frame 22 and 23 and coupled to the lower frame 18, wherein the mount bracket 24 may include: a gear mount 24a to which the driving pulley assembly 31 is rotatably coupled; and a motor mount 24b extending from the gear mount 24a.

The driving pulley assembly 31 may include: a lower pulley 31b around which the belt 32 is wound; a pulley shaft 31a providing a rotation axis of the lower pulley 31b; and a bearing 31c positioned next to and coupled to the lower pulley 31b, the bearing 31c having an outer diameter coupled to the gear mount 24a and an inner diameter coupled to the pulley shaft 31a.

The display device may further include: a fixing bracket 60 coupled to the mount bracket 24; a gear box 62 coupled to the fixing bracket 60 and connected to the pulley shaft 31a of the lower pulley 31b; and a motor 61 coupled to the fixing bracket 60 and providing torque to the gear box 62.

The display panel 11 may further include: an S-PCB 14 elongated along the lower side of the display panel 11 and spaced apart from the display panel 11; and a COF 15 electrically connecting the display panel 11 and the S-PCB 14, wherein the S-PCB 14 may be disposed on the lower frame 18.

The display device may further include a PCB cover 19 facing the lower frame 18 and covering the S-PCB 14.

The display device may further include a mount bracket 24 adjacent to the distal end of the side frame 22 and 23, and coupled to the lower frame 18, wherein the mount bracket 24 may include: a gear mount 24a to which the driving pulley assembly 31 is rotatably coupled; and a roller mount 24b extending from the gear mount 24a, wherein the roller mount 24b may have at least one roller hole 24d formed through the roller mount 24b.

The roller 72 may be rotatably coupled to the at least one roller hole 24d.

The display device may further include a guide roller 73 extending in a longitudinal direction of the roller 72 and disposed next to the roller 72, wherein the roller mount 24b may include a pair of roller holes 24d to which the roller 72 and the guide roller 73 are coupled, wherein the guide roller 73 may contact the light-shielding film 45.

The bar 40 may further include a belt fixer 43 disposed adjacent to the belt 32 and coupled to a distal end of the bar 40, wherein the belt 32 may be disposed between the distal end of the bar 40 and the belt fixer 43, wherein the belt fixer 43 may be fixed to the distal end of the bar 40 while pressing the belt 32.

A display device includes: a display panel 11 configured to display an image and having light transparency; a transparent panel 13 facing the display panel 11; a side frame 22 and 23 adjacent to a side edge of the display panel 11 and elongated along the side edge of the display panel 11, and coupled to the transparent panel 13; a belt 32 embedded in the side frame 22 and 23 and moving in a longitudinal direction of the side frame 22 and 23; a bar 40 elongated in a direction intersecting the side frame 22 and 23, the bar 40 having one end fixed to the belt 32; a rotatable roller 72 adjacent to a lower side connected to the side edge of the display panel 11, and elongated along the lower side of the display panel 11; and a light-shielding film 45 having one end fixed to the bar 40 and another end coupled to the roller 72, such that when the bar 40 moves, the light-shielding film 45 is wound around or unwound from the roller 72, wherein the bar 40 includes: a plurality of pieces 41 and 42 facing each other so that the light-shielding film 45 is inserted between the facing pieces; and a belt fixer 43 opposite to the plurality of pieces 41 and 42 with respect to the belt 32, and coupled to the plurality of pieces 41 and 42.

The plurality of pieces 41 and 42 may include: a first piece 41 having an elongated plate shape; and a second piece 42 elongated to face the first piece 41, wherein the first piece 41 may include a fixing rib 41c protruding from an outer surface of the first piece 41 at a position between the first piece 41 and the second piece 42, and extending in a longitudinal direction of the first piece 41, wherein the light-shielding film may contact the fixing rib 41c.

The second piece 42 may include a rib groove 42a into which the fixing rib 41c of the first piece 41 is inserted, the rib groove 42a recessed from an outer surface of the second piece 42 at a position between the second piece 42 and the first piece 41, and extending in a longitudinal direction of the second piece 42.

The light-shielding film 45 may be gripped by the fixing rib 41c and the rib groove 42a, and may contact the first piece 41 and the second piece 42.

The second piece 42 may have a rounded edge 42R around which the light-shielding film 45 is wound.

A distal end of the light-shielding film 45 may be disposed between the first piece 41 and the second piece 42, and may be opposite to the rounded edge 42R with respect to the fixing rib 41c.

The first piece 41 may include: a first part 41a facing the second piece 42; and a second part 41b extending from the first part 41a while covering a lower surface of the second piece 42, wherein the distal end of the light-shielding film 45 may be disposed between the second part 41b of the first piece 41 and the second piece 42.

The second piece 42 may include a horizontal fastening hole 42h formed in a thickness direction of the second piece 42 at a position between the rib groove 42a and the second part 41b of the first piece 41, wherein the first piece 41 may include a horizontal fastening hole 42h passing through the first part 41a in a thickness direction and corresponding to the horizontal fastening hole 42h of the second piece 42, wherein a screw may pass through the light-shielding film 45 to be coupled to the horizontal fastening hole 41h of the first piece 41 and the horizontal fastening hole 42h of the second piece 42.

The second piece 42 may include a vertical fastening hole 42h facing the second part 41b of the first piece 41 and formed in a width direction of the second piece 42, wherein the first piece 41 may include a vertical fastening hole 41h passing through the second part 41b in a thickness direction and corresponding to the vertical fastening hole 42h of the second piece 42, wherein a screw may pass through the light-shielding film 45 to be coupled to the vertical fastening hole 41h of the first piece 41 and the vertical fastening hole 42h of the second piece 42.

The belt 32 may be a timing belt, wherein the belt fixer 43 may include a fixer body 43a having a gear surface 43c engaged with a gear of the belt 32.

The belt fixer 43 may be fixed by a screw to at least one of the plurality of pieces 41 and 42 of the bar 40, wherein the screw may pass through the belt 32.

The belt fixer 43 may further include a fixer tail 43b extending from the fixer body 43a in a longitudinal direction of the belt 32.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

What is claimed is:

1. A display device comprising:
a display panel displaying an image and having light transparency;
a transparent panel facing the display panel;
a side frame adjacent to a side edge of the display panel, and the side frame elongated along the side edge of the display panel and coupled to the transparent panel;
a belt disposed in the side frame and moving in a longitudinal direction of the side frame;
a bar elongated in a direction intersecting the side frame, the bar having one end fixed to the belt;
a rotatable roller disposed adjacent to a lower side connected to the side edge of the display panel and elongated along the lower side of the display panel;
and a cover layer having one end fixed to the bar and another end coupled to the roller, such that when the bar moves, the cover layer is wound around or unwound from the roller,
wherein the bar comprises:
a plurality of pieces facing each other so that the cover layer is inserted between the facing pieces; and
a belt fixer opposite to the plurality of pieces with respect to the belt, and the belt fixer coupled to the plurality of pieces.

2. The display device of claim 1, wherein the plurality of pieces comprises:
a first piece having an elongated plate shape; and
a second piece elongated to face the first piece,
wherein the first piece comprises a fixing rib protruding from an outer surface of the first piece between the first piece and the second piece and extending in a longitudinal direction of the first piece,
wherein the cover layer contacts the fixing rib.

3. The display device of claim 2, wherein the second piece comprises a rib groove into which the fixing rib of the first piece is inserted, the rib groove recessed from an outer surface of the second piece between the second piece and the first piece and extending in a longitudinal direction of the second piece.

4. The display device of claim 3, wherein the cover layer is gripped by the fixing rib and the rib groove and contacts the first piece and the second piece.

5. The display device of claim 4, wherein the second piece has a rounded edge around which the cover layer is wound.

6. The display device of claim 5, wherein a distal end of the cover layer is disposed between the first piece and the second piece and is opposite to the rounded edge with respect to the fixing rib.

7. The display device of claim 5, wherein the first piece comprises:
a first part facing the second piece; and
a second part extending from the first part and covering a lower surface of the second piece,
wherein the distal end of the cover layer is disposed between the second part of the first piece and the second piece.

8. The display device of claim 7, wherein the second piece comprises a horizontal fastening hole formed in a thickness direction of the second piece between the rib groove and the second part of the first piece,
wherein the first piece comprises a horizontal fastening hole passing through the first part in a thickness direction and corresponding to the horizontal fastening hole of the second piece,
wherein a screw passes through the cover layer to be coupled to the horizontal fastening hole of the first piece and the horizontal fastening hole of the second piece.

9. The display device of claim 7, wherein the second piece comprises a vertical fastening hole facing the second part of the first piece and formed in a width direction of the second piece,
wherein the first piece comprises a vertical fastening hole passing through the second part in a thickness direction and corresponding to the vertical fastening hole of the second piece,
wherein a screw passes through the cover layer to be coupled to the vertical fastening hole of the first piece and the vertical fastening hole of the second piece.

10. The display device of claim 1, wherein the belt is a timing belt,
wherein the belt fixer comprises a fixer body having a gear surface engaged with a gear of the belt.

11. The display device of claim 10, wherein the belt fixer is fixed by a screw to at least one of the plurality of pieces of the bar,
wherein the screw passes through the belt.

12. The display device of claim 11, wherein the belt fixer further comprises a fixer tail extending from the fixer body in a longitudinal direction of the belt.
